(19) United States
(12) Patent Application Publication
(10) Pub. No.: US 2024/0175137 A1
(43) Pub. Date: May 30, 2024

(54) VAPOR PHASE PRECURSOR DELIVERY SYSTEM

(71) Applicant: ASM IP Holding B.V., Almere (NL)

(72) Inventors: Dieter Pierreux, Pepingen (BE); Jan Deckers, Kessel-Lo (Leuven) (BE); Theodorus G.M. Oosterlaken, Oudewater (NL)

(21) Appl. No.: 18/517,837

(22) Filed: Nov. 22, 2023

Related U.S. Application Data
(60) Provisional application No. 63/384,997, filed on Nov. 25, 2022.

(51) Int. Cl. C23C 16/52; C23C 16/08; C23C 16/448; C23C 16/455

(52) U.S. Cl. CPC C23C 16/52; C23C 16/08; C23C 16/448; C23C 16/45561

(57) ABSTRACT

A vapor phase precursor delivery system for delivering a vapor phase precursor for depositing a layer in a vapor phase deposition apparatus is disclosed. The vapor phase precursor delivery system having: a plurality of vessels constructed and arranged to store and vaporize the same precursor; and a gas inlet and a gas outlet operably connected with one or more of the plurality of vessels. A vapor phase deposition apparatus, such as for example a vertical furnace may have such a vapor phase precursor delivery system for depositing a layer on a substrate.

### CROSS-REFERENCE TO RELATED APPLICATION(S)

This application claims the benefit of U.S. Provisional Application 63/384,997 filed on Nov. 25, 2022, the entire contents of which are incorporated herein by reference.

### FIELD OF INVENTION

The disclosure generally relates to a vapor phase precursor delivery system for delivering a vapor phase precursor. In particular, the disclosure relates to a vapor phase precursor delivery system comprising:
a plurality of vessels constructed and arranged to store and vaporize a precursor; and
a gas inlet and a gas outlet operably connected with one or more of the plurality of vessels.

The disclosure further relates to a vapor phase deposition apparatus comprising such a vapor phase precursor delivery system for depositing a layer on a substrate.

### BACKGROUND OF THE DISCLOSURE

A vapor phase precursor delivery system for delivering a vapor phase precursor for depositing a layer on a substrate in a reactor of a vapor phase deposition apparatus may exhibit certain challenges. One of these challenges may be that the precursor delivery system may deliver to less vapor and the precursor delivery may become a bottle neck for the productivity of the deposition apparatus. One of the reasons that the precursor delivery system may be delivering to less precursor is that the vapor pressure of the precursor may be very low. This may be especially the case with solid precursors.

Another bottle neck for the productivity of the vapor phase deposition system may be that the vapor production of the precursor delivery system may be not constant over time.

### SUMMARY OF THE DISCLOSURE

It may be an objective to provide a vapor phase precursor delivery system for delivering a vapor phase precursor.

Accordingly, there may be provided a vapor phase precursor delivery system comprising:
a plurality of vessels constructed and arranged to store and vaporize a precursor; and,
a gas inlet and a gas outlet operably connected with one or more of the plurality of vessels. The system may further comprise a plurality of outlet valves to control the gas flow out of the one or more vessels of the plurality of vessels to the gas outlet. The plurality of vessels may be constructed and arranged for storing and vaporizing the same precursor. The plurality of outlet valves may control the gas flow comprising the same precursor out of the one or more vessels of the plurality of vessels to the gas outlet.

Also, a vapor phase deposition apparatus may be provided. The apparatus may comprise a vapor phase precursor delivery system for delivering a vapor phase precursor for depositing a layer on a substrate. The apparatus may be a vertical furnace comprising a reactor constructed and arranged to load a boat with a plurality of substrates. The vapor phase precursor delivery system may be constructed and arranged for delivering the vapor phase precursor for depositing a layer on the substrates in the reactor.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIGS. 1A and 1B disclose a vapor phase precursor delivery system according to the prior art.

FIG. 2 discloses a vapor phase precursor delivery system according to an embodiment.

FIG. 3 discloses a vapor phase precursor delivery system according to a further embodiment

FIG. 4 shows a graph of the vapor concentration delivered by a vapor phase precursor delivery system according to a further embodiment.

FIG. 5 discloses a cross-section of a vessel for the vapor phase precursor delivery system of FIGS. 2 and 3.

FIG. 6 discloses a vapor phase precursor delivery system according to a further embodiment.

FIG. 7 discloses a vapor phase precursor delivery system according to a further embodiment.

FIG. 8 discloses a vapor phase precursor delivery system according to a further embodiment.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

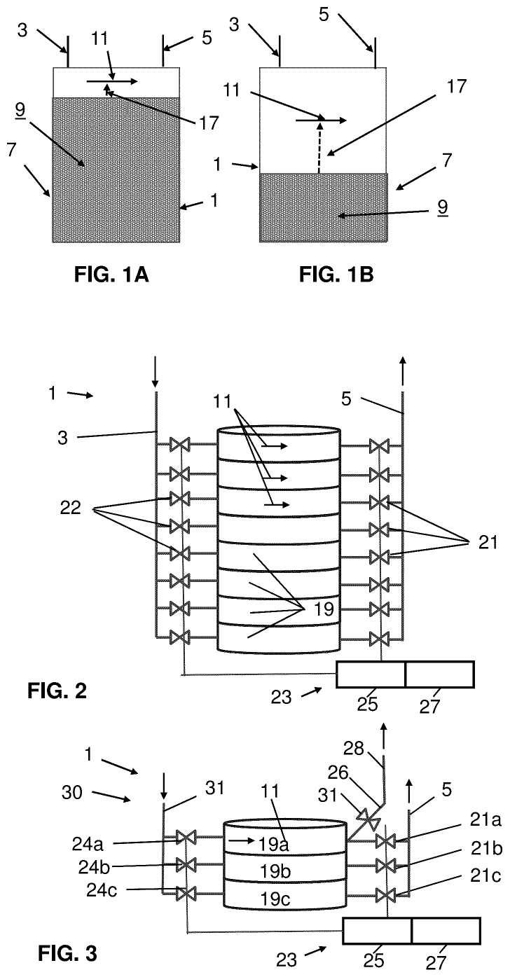

FIGS. 1A and 1B disclose a vapor phase precursor delivery system 1 comprising: a gas inlet 3 and a gas outlet 5 according to the prior art. The vapor phase precursor delivery system 1 may comprise a tank 7 constructed and arranged for storing a precursor 9. A gas flow 11 may be created between the gas inlet 3 and the gas outlet 5 for example with an inert gas like nitrogen within the tank 7. The gas flow 11 may cause some precursor 9 to vaporize 17 into the gas flow 11 which may be transported out of the tank 7 via the gas outlet 5.

The vaporization of the precursor 9 may be dependent on the level of the precursor in the tank 7 for storing the precursor. Since the level of the precursor 9 in the tank 7 during use of the system 1 may be lowered from a relatively full tank 7 in FIG. 1A to a relatively empty tank 7 in FIG. 1B the quantity of the precursor 9 vaporized 17 in the system 1 may also be lower since the gas flow 11 is further away from the precursor.

FIG. 2 discloses a vapor phase precursor delivery system 1 according to an embodiment comprising a gas inlet 3 and a gas outlet 5. The vapor phase precursor delivery system 1 may comprise a plurality of vessels 19 constructed and arranged to store and vaporize the precursor; and operably connected with the gas inlet 3 and the gas outlet 5.

The vessel 19 may be constructed and arranged for creating a gas flow 11 from the gas inlet 3 to the gas outlet 5 through the vessel 19 for example with an inert gas like nitrogen or a noble gas such as helium, neon, argon, krypton, or xenon. The gas flow 11 may cause some precursor in the vessel 19 to vaporize into the gas flow 11 which may be transported out of the vessel 19 via the gas outlet 5. The amount of the precursor in the vessel 19 during use of the system 1 may be decreasing. The amount of precursor vaporized 17 in the system may therefore be decreasing. This may be disadvantageous because the quantity of precursor in the gas flowing out of the gas outlet 5 may therefore decrease.

The plurality of vessels 19 may be constructed and arranged to store and vaporize the same precursor. The system 1 may comprise a plurality of outlet valves 21 to control the gas flow 11 comprising the precursor out of the one or more vessels of the plurality of vessels 19 to the gas outlet 5. The amount of the same precursor vaporized in the system 1 may be kept substantially constant by switching of the outlet valves 21. For example, the system 1 may switch from a vessel 19 that has been used some time and is exhausted to a fresh vessel 19 which can deliver more. This is advantageous because the quantity of the same precursor in the gas flowing out of the gas outlet 5 may therefore remain substantially constant.

The plurality of vessels 19 may be constructed and arranged for storing the same solid or a liquid precursor. For example, the same precursor in the vessels 19 may comprise a transition metal halide such as a transition metal chloride, a transition metal bromide, a transition metal fluoride or a transition metal iodide.

The same precursor in the vessels 19 may be a transition metal chloride. For example, the same precursor may be a hafnium tetra chloride, a molybdenum pentachloride, a molybdenum dichloride dioxide, or a zirconium chloride.

The outlet valves 21 may be operably connected to a controller 23 to control the opening and closing of the outlet valves 21 to control the gas flow 11 of the same precursor out of the vessels 19. The controller 23 may be connected to the outlet valves 21 in a way to control the outlet valves 21 individually.

The controller may comprise a processor 25 and a memory 27. The memory 27 may be programmed with a program to control the opening and closing of the outlet valves 21 to control the gas flow 11 of the precursor. For example, the memory 27 may be programmed with a program to open an outlet valve of the plurality of outlet valves 21 while keeping the other outlet valves of the plurality of outlet valves 21 closed.

The amount of the same precursor vaporized in the system 1 may thereby be kept substantially constant. This is advantageous because the quantity of the same precursor in the gas flowing out of the gas outlet 5 may remain therefore substantially constant as well.

The system may comprise a plurality of inlet valves 22 to connect the gas inlet 3 with one or more of the vessels 19 of the plurality of vessels. 13. The plurality of inlet valves 22 may be operably controlled by the controller 23. The controller 23 may comprise a processor 25 and a memory 27.

The memory 27 of the controller 23 may be programmed with a program when executed on the processor 25 to control the outlet valves 21 simultaneous with the inlet valves 22 of the corresponding vessel 19 of the plurality of vessels. In this way the gas flow 11 from the gas inlet 3 may push the vaporized precursor out of the vessel 19 into the gas outlet 5.

FIG. 3 discloses a vapor phase precursor delivery system 1 according to an embodiment comprising a gas inlet 3 and a gas outlet 5. The system 1 may comprise a plurality of vessels 19a, 19b and 19c constructed and arranged for storing the same precursor. The system 1 may comprise a plurality of outlet valves 21a, 21b and 21c to control the gas flow 11 comprising the same precursor out of the one or more vessels of the plurality of vessels 19a, 19b and 19c to the gas outlet 5. The plurality of vessels 19 may be 2 to 20, preferably 3 to 8 or 4 to 6 vessels 19. The plurality of outlet valves 21 may be 2 to 20, preferably 3 to 8 or 4 to 6 outlet valves.

The outlet valves 21a, 21b and 21c may be operably connected to a controller 23 to control the opening and closing of the outlet valves 21a, 21b and 21c to control the gas flow 11 comprising the same precursor out of the vessels 19a, 19b and 19c. The controller 23 may be connected to the outlet valves 21a, 21b and 21c to control the outlet valves 21 individually.

The controller 23 may comprise a processor 25 and a memory 27. The memory 27 of the controller 23 may be programmed with a program when executed on the processor 25 to control the opening and closing of the outlet valves 21a, 21b and 21c to control the gas flow 11 comprising the same precursor. For example, the memory 27 of the controller 23 may be programmed with a program when executed on the processor 25 to:
1) open the first outlet valve 21a of the plurality of outlet valves 21a, 21b and 21c while keeping the second and third outlet valves 21b and 21c closed;
2) open the second outlet valve 21b of the plurality of outlet valves 21a, 21b and 21c while closing or keeping closed the first and third outlet valves 21a and 21c after a pulse time of for example 1 to 8 second preferably 2 to 4 seconds; and,
3) open the third outlet valve 21c of the plurality of outlet valves 21a, 21b and 21c while closing or keeping closed the first and second outlet valves 21a and 21b after a pulse time of for example 1 to 8 second preferably 2 to 4 seconds.
4) The program may be repeated at 1) again by opening the first outlet valve 21a of the plurality of outlet valves 21a, 21b while keeping the second and third outlet valves 21b and 21c closed.
   In this way the amount of the same precursor vaporized in the system 1 may be kept substantially constant by switching of the outlet valves 21a, 21b, 21c.

The memory 27 of the controller 23 may be programmed with a program when executed on the processor 25 to sequentially open and close all outlet valves of the plurality of outlet valves. This is advantageous because the quantity of precursor in the gas flowing out of the gas outlet 5 may remain therefore substantially constant as well.

The memory 27 of the controller 23 may be programmed with a program when executed on the processor 25 to close the open outlet valve and simultaneously open a different outlet valve of the plurality of outlet valves to maintain the gas flow comprising the same precursor while keeping the other outlet valves the plurality of outlet valves closed to recharge the vessel of the closed outlet valves. When the valves 12a, 21b, 21 c are closed the corresponding vessel 19a, 19b, 19c may be recharged for re-use.

The system 1 may be provided with a refill arrangement 30, for example a fill inlet 31 provided with a fill valves 24a, 24b, and 24c for filling the vessel 19a, 19b, 19c with precursor. Based on the precursor the fill inlet 31 and the fill valves 24a, 24b, and 24c may be relatively big and take the form of an opening with a lid for solid or liquid precursor.

In case of solid precursors, the refill arrangement may employ a precursor loading method by for example having a precursor saturated, inert gas stream to flow through the precursor vessel 19. Precursor vapor may then be deposited on a carrier provided to the precursor vessel 19. The carrier (not shown) may be a meandering duct or open-celled foam. The inert gas after leaving a substantial portion of the vapor precursor deposited in the carrier may flow out at the other side. The inert gas may be flown through the reaction chamber and through the exhaust of the vapor phase deposition apparatus employing the vapor delivery system, which makes that you may have to shut down the apparatus for a refill.

To avoid that you may have to shut down the apparatus for a refill a bypass line 26 connecting the outlet of vessel 19a directly to the exhaust 28 of the vapor phase deposition apparatus, or of the semiconductor fab employing the vapor delivery system 1 may be provided to the refill arrangement 30. The bypass line 26 may be provided with a bypass valve 32 to control the flow of the inert gas after leaving a substantial portion of the vapor precursor deposited in the carrier to the exhaust 28. The bypass valve 31 may be operationally connected to the controller 25. As depicted in FIG. 3 a bypass line 26 may connect the outlet of vessel 19a directly to the exhaust 28 but the other vessels 19b and 19c may similarly be connected to the exhaust 28 with a separate bypass valve 31 under control of the controller 25. One of the vessels may be refilled with solid precursor while the other vessels continue operation.

The memory 27 of the controller 23 may be programmed with a program when executed on the processor 25 to control the closing of the outlet valves 21a, 21b, 21c of the vessel 19a, 19b, 19c to be closed during refill of the respective vessel 19a, 19b, 19c. The memory 27 of the controller 23 may be programmed with a program when executed on the processor 25 to open the fill valves 24a, 24b, and 24c of the vessels 19a, 19b, 19c only when the respective outlet valves 21a, 21b, 21c of the respective vessels 19a, 19b, 19c are closed. The plurality of fill valves may be 2 to 20, preferably 3 to 8 or 4 to 6 fill valves 24. The memory 27 of the controller 23 may be programmed with a program when executed on the processor 25 to control the opening of the bypass valves 31 during refill of the respective vessel 19a, 19b, 19c.

The memory 27 of the controller 23 may be programmed with a program when executed on the processor 25 to open at least two of the plurality of outlet valves 21a, 21b, 21c together to control the gas flow 11 comprising the same precursor. The other valves of the plurality of valves 21a, 21b, 21c may be controlled to be closed. The memory 27 of the controller 23 may be programmed with a program when executed on the processor 25 to close one of the at least two open outlet valves and simultaneous open a different outlet valve of the plurality of outlet valves 21a, 21b, 21c to maintain the gas flow 11 comprising the same precursor.

For example, the memory 27 of the controller 23 may be programmed with a fade in fade out program when executed on the processor 25 to:
1) open the first outlet valve 21a of the plurality of outlet valves 21a, 21b and 21c while keeping the second and third outlet valves 21b and 21c closed;
2) open the second outlet valve 21b of the plurality of outlet valves 21a, 21b and 21c while keeping the first outlet valve 21a open after some time when the first vessel 19a delivers less precursor, for example 0.5 to 5 second preferably 1 to 3 seconds; and,
3) open the third outlet valve 21c of the plurality of outlet valves 21a, 21b and 21c while closing the first outlet valve 21a and keeping the second outlet valve 21b open after some time when the first vessel 19a delivers no precursor anymore and the second vessel 19b delivers less precursor, for example 0.5 to 5 second preferably 1 to 3 seconds.
   The program may be repeated at 1) again by opening the first outlet valve 21a while keeping the third outlet valves 21c open and closing the second outlet valve 21b.

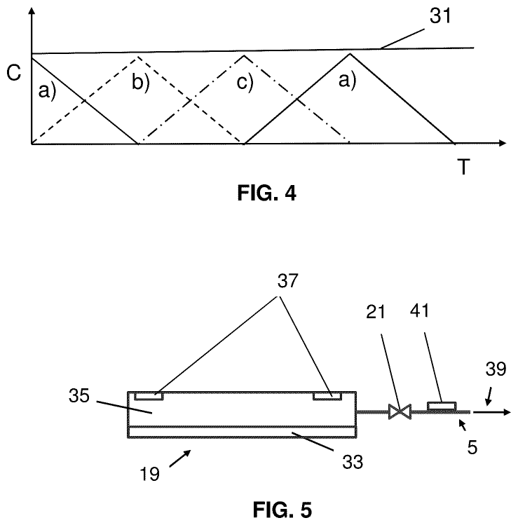

FIG. 4 shows a graph of the vapor concentration C over time T delivered by the vapor phase precursor delivery system 1 of FIG. 3 when the fade in fade out program is running. The contribution of the different vessels 19a, 19b and 19c to the concentration C is depicted by the lines a, b, and c respectively. It is shown that the concentration C can be kept substantially constant while the contribution of the different vessels 19a, 19b and 19c (depicted by the lines a, b, and c respectively) fades in and out and therefore varies significantly.

FIG. 5 discloses a cross section of a vessel 19 for the vapor phase precursor delivery system 1 of FIGS. 2 and 3. The vessel 19 may be provided with a heating element 33. The vessel 19 may be constructed and arranged to store and vaporize a solid or liquid precursor in the interior 35 of the vessel 19. The heating element 33 may heat the precursor in the interior 35 of the vessel 19. The heating of the precursor may vaporize, e.g. sublimate or evaporate the precursor.

The vessel 19 may be provided with a weight sensor 37 to measure a weight of the precursor in the vessel 19. The weight sensor 37 may be a piezoelectric sensor which may be used to measure stress in the which may be used for calculating the weight of the precursor. When the precursor is evaporated from the vessel 19 the weight may decrease. The weight sensor 37 may therefore be used to calculate when the vessel 19 is empty and needs to be refilled. The weight sensor 37 may also be used to calculate the evaporated precursor. The evaporated precursor may be used to calculate the concentration of the precursor in the gas flow 39. The concentration of the precursor in the gas flow 39 may be used to determine when the vessel 19 may be recharged. The concentration of the precursor in the gas flow 39 may even be used to calculate the amount of deposition on the substrate.

The gas outlet 5 of the vessel 19 may also be provided with an gas outlet weight sensor 41 to measure a weight of the precursor deposited on the outlet weight sensor 41 in the gas outlet. This outlet weight sensor 41 also may be a piezoelectric sensor which may be used to measure stress which may be used for calculating the weight of the precursor deposited. When the precursor is vaporized from the vessel 19 the amount of precursor deposited may decrease. The outlet weight sensor 41 may therefore be used to calculate when the vessel 19 is empty and needs to be refilled. The outlet weight sensor 41 may also be used to calculate the evaporated precursor. The sublimated or evaporated precursor may be used to calculate the concentration of the precursor in the gas flow 39. The concentration of the precursor in the gas flow 39 may be used to determine when the vessel 19 may be recharged. The concentration of the precursor in the gas flow 39 may even be used to calculate the amount of deposition on the substrate.

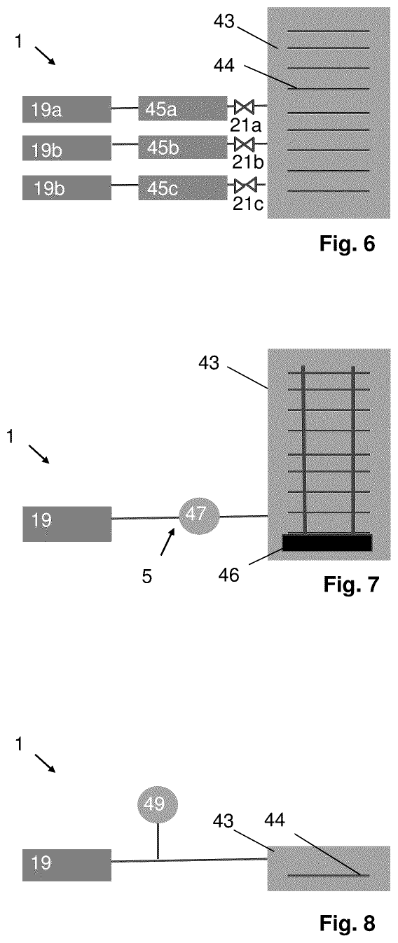

FIG. 6 discloses a vapor phase precursor delivery system 1 according to a further embodiment arranged for delivering a precursor. The system 1 may be provide with a plurality of vessels 19a, 19b and 19c constructed and arranged to deliver the same precursor to a reaction chamber 43. The precursor may be used to deposit a layer on a substrates 44 loaded in the reaction chamber 43. A vapor storages 45 may be provided between the vessels 19 and outlet valves 21 to store precursor that has been vaporized. A plurality of vapor storages 45a, 45b and 45c may be provided between the vessels 19a, 19b and 19c and outlet valves 21a, 21b and 21c to store the precursor that has been vaporized. Storing of vapor phase precursor may be advantageously because the amount of precursor provided out of the vessel in one go may become larger. The plurality of vapor storages may be 2 to 20, preferably 3 to 8 or 4 to 6 vapor storages 45.

FIG. 7 discloses a vapor phase precursor delivery system 1 according to a further embodiment. A filter 47 may be provided between vessel 19 and the reaction chamber 43 to filter particles out of vapor phase precursor before delivery to the sensitive reaction chamber 43. The filter 47 may be located between the vessel and the gas outlet 5 to filter the vapor phase precursor. The filter 47 may even be located in the gas outlet 5 of the system 1 before the vapor phase precursor may reach the reaction chamber 43.

The reaction chamber 43 may be a part of a deposition apparatus. The deposition apparatus may be a vertical furnace. The reaction chamber 43 in the vertical furnace may be constructed and arranged to load a boat 46 with a plurality of substrates 44. The system 1 may be constructed and arranged for delivering the same vapor phase precursor for depositing a layer on the substrates 44 in the boat 46 in the reaction chamber 43.

The reaction chamber in this embodiment may also be constructed and arranged to hold and process a single substrate 44.

FIG. 8 discloses a vapor phase precursor delivery system according to a further embodiment. A pressure sensor 49 may be provided between the vessel 19 and the reaction chamber 43 to measure the pressure of the gas flow comprising the same precursor to the reaction chamber 43. The pressure sensor may be operably connected with the controller. The reaction chamber in this embodiment may be constructed and arranged to hold and process a single substrate 44 with the same precursor. The reaction chamber 43 may also be constructed and arranged to load a plurality of substrates 44.

The vapor phase precursor delivery system 1 may comprise vessels 19 constructed and arranged to store and sublimate the same solid precursor. The vessel may be constructed and arranged to store and sublimate a metal halide such as for example a transition metal halide. The transition metal halide may be a transition metal chloride. The vessel may be constructed and arranged to store and sublimate, for example, hafnium tetra chloride, molybdenum pentachloride, molybdenum dichloride dioxide, or zirconium chloride as the metal chloride.

The system 1 may be provided with a refill arrangement comprising a fill inlet to provide the solid precursor to the vessel 19 and a lid to close the fill inlet. The lid may be provided with a grip for an operator to open the fill inlet.

The system 1 may be constructed and arranged to store and vaporize a liquid with a relatively high viscosity compared to the viscosity of water.

The vapor phase precursor delivery system 1 may be used in a vapor phase deposition apparatus for delivering the same vapor phase precursor for depositing a layer on a substrate. The vapor phase deposition apparatus may be a vertical furnace comprising a reactor constructed and arranged to load a boat with a plurality of substrates and the vapor phase precursor delivery system is constructed and arranged for delivering a vapor phase precursor for depositing a layer on the substrates in the reactor. A vertical furnace suitable to use the vapor phase precursor delivery system 1 may be described in U.S. Pat. No. 7,732,350 B2 for example incorporated herein by reference.

Some customers may keep the vapor phase precursor delivery system 1 in a clean or dirty sub fab instead of in the vapor phase deposition apparatus. This may be especially the case when the vapor phase precursor delivery system 1 is very bulky. A clean sub fab may be one floor below the apparatus. A dirty sub fab may be two floors below the apparatus. Other customer may prefer it in the vapor phase deposition apparatus itself to keep the length of the lines connecting the vapor phase precursor delivery system 1 with the vapor phase deposition apparatus as short as possible.

The illustrations presented herein are not meant to be actual views of any particular material, structure, or device, but are merely idealized representations that are used to describe embodiments of the disclosure.

The implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various processes, systems, and configurations, and other features, functions, acts, and/or properties disclosed herein, as well as any and all equivalents thereof.

1. A vapor phase precursor delivery system comprising:
a plurality of vessels constructed and arranged to store and vaporize a precursor; and
a gas inlet and a gas outlet operably connected with the plurality of vessels, wherein the plurality of vessels are constructed and arranged to store and vaporize the same precursor and the system further comprises a plurality of outlet valves to control a gas flow comprising the same precursor out of one or more vessels of the plurality of vessels to the gas outlet.

2. The system according to claim 1, wherein the outlet valves are operably connected to a controller to control the opening and closing of the outlet valves to control the gas flow comprising the same precursor.

3. The system according to claim 2, wherein the controller comprises a processor and a memory, wherein the memory of the controller is programmed with a program when executed on the processor to control the opening and closing of the outlet valves to control the gas flow comprising the same precursor to the gas outlet.

4. The system according to claim 3, wherein the memory of the controller is programmed with a program when executed on the processor to open an outlet valve of the plurality of outlet valves while keeping the other outlet valves of the plurality of outlet valves closed to create the gas flow comprising the same precursor to the gas outlet.

5. The system according to claim 4, wherein the memory of the controller is programmed with a program when executed on the processor to close the open outlet valve and open a different outlet valve of the plurality of outlet valves to maintain the gas flow comprising the same precursor to the gas outlet.

6. The system according to claim 5, wherein the memory of the controller is programmed with a program when executed on the processor to sequentially open and close all outlet valves of the plurality of outlet valves.

7. The system according to claim 2, wherein the system is provided with a refill arrangement to refill a vessel of the plurality of vessels.

8. The system according to claim 7, wherein the controller is programmed with a program to close the outlet valve of the vessel to be refilled during refill.

9. The system according to claim 7, wherein the controller is operably connected to the refill arrangement and comprises a processor and a memory, wherein the memory is programmed with a program to control the opening and closing of the outlet valves and the memory is programmed with a program to refill a vessel when its outlet valve is closed by the controller.

10. The system according to claim 3, wherein the memory of the controller is programmed with a program when executed on the processor to open at least two of the plurality of outlet valves to control the gas flow comprising the same precursor.

11. The system according to claim 10, wherein the memory of the controller is programmed with a program when executed on the processor to close one of the at least two open outlet valves and open a different outlet valve of the plurality of outlet valves to maintain the gas flow comprising the same precursor.

12. The system according to claim 2, wherein the system comprises a plurality of inlet valves to connect the gas inlet with one or more of the vessels of the plurality of vessels and the inlet valves are operably controlled by the controller.

13. The system according to claim 12, wherein the controller comprises a processor and a memory and the memory of the controller is programmed with a program when executed on the processor to control the outlet valves simultaneous with the inlet valves of the corresponding vessel of the plurality of vessels.

14. The system according to claim 2, wherein the system comprises a plurality of bypass valves to connect one or more of the vessels of the plurality of vessels with the exhaust and the bypass valves are operably controlled by the controller.

15. The system according to claim 1, wherein a vapor storage is provided between a vessel of the plurality of vessels and an outlet valve of the plurality of outlet valves to store vapor phase precursor.

16. The system according to claim 1, wherein a filter is provided between a vessel of the plurality of vessels and the gas outlet to filter the vapor phase precursor.

17. The system according to claim 1, wherein a vessel of the plurality of vessels is provided with a heating element to heat the vessel.

18. The system according to claim 1, wherein a vessel of the plurality of vessels is provided with a weight sensor to measure a weight of the vessel.

19. The system according to claim 1, wherein the vessels are constructed and arranged to store and vaporize a solid precursor.

20. The system according to claim 1, wherein the vessels are constructed and arranged to store and vaporize a transition metal halide.

21. A vapor phase deposition apparatus comprising a vapor phase precursor delivery system according to claim 1 for delivering a vapor phase precursor for depositing a layer on a substrate.

22. The vapor phase deposition apparatus according to claim 21, wherein the apparatus is a vertical furnace comprising a reaction chamber constructed and arranged to load a boat with a plurality of substrates and the vapor phase precursor delivery system is constructed and arranged for delivering a vapor phase precursor for depositing a layer on the substrate in the reaction chamber.
